(19) United States
(12) Patent Application Publication
(10) Pub. No.: US 2026/0157007 A1
(43) Pub. Date: Jun. 4, 2026

(54) DISPLAY DEVICE

(71) Applicant: LG Display Co., Ltd., Seoul (KR)

(72) Inventors: JongHyun PARK, Chilgok-gun (KR); SangMoo SONG, Seoul (KR); Minho LEE, Daegu (KR)

(73) Assignee: LG Display Co., Ltd., Seoul (KR)

(21) Appl. No.: 19/207,890

(22) Filed: May 14, 2025

(30) Foreign Application Priority Data
Dec. 3, 2024 (KR) 10-2024-0177470

(51) Int. Cl. H10H 29/855; H01L 25/075; H10H 29/37; H10K 59/122; H10K 59/80

(52) U.S. Cl. CPC H10H 29/8552; H10H 29/37; H10K 59/122; H10K 59/879; H10W 90/00

(57) ABSTRACT

According to an aspect of the present disclosure, a display device includes a substrate including an active area, the active area having a first active area and a second active area that encloses the first active area. A light emitting diode is disposed in the active area and includes an emission area. An optical member is disposed on the light emitting diode. In an upper area or a lower area of the second active area, a center of the optical member is shifted from a center of the emission area to enhance display performance.

### CROSS-REFERENCE TO RELATED APPLICATIONS

This application claims the priority of Korean Patent Application No. 10-2024-0177470 filed on Dec. 3, 2024, in the Korean Intellectual Property Office, the disclosure of which is incorporated herein by reference.

### BACKGROUND

### Technical Field

The present disclosure relates to a display device, and more particularly to a display device in which a viewing angle is controllable.

### Description of the Related Art

As the technology in modern society develops, display devices are used in various ways to provide information to users. The display devices include not only electronic signs which simply transmit visual information in one direction, but also various electronic devices which require a higher level of technology to check user's input and provide information in response to the checked input.

For example, a display device is included in a vehicle to provide various information to a driver and passengers of the vehicle. However, the display device of the vehicle needs to appropriately display contents without interrupting the operation of the vehicle. For example, the display device needs to limit the display of the contents which may reduce the concentration on the driving while the vehicle is in operation.

### BRIEF SUMMARY

The display device includes a configuration where each subpixel contains two light-emitting diodes, one paired with an optical member that provides a wide viewing angle and the other with an optical member that limits the viewing angle. This allows the device to switch between a shared viewing mode and a private viewing mode, making it particularly useful in automotive settings where content visibility can be adjusted to reduce driver distraction. In the outer regions of the display, the optical members are intentionally shifted relative to the emission centers to correct brightness irregularities and ensure more uniform luminance across the screen.

The design also incorporates light-blocking barrier layers and optical elements that work in combination with the black matrix and touch electrodes to reduce or minimize lateral light leakage while maintaining full touch functionality. Together with a multilayer encapsulation structure and carefully controlled optical paths, this approach supports high image quality, energy efficiency, and reliable performance in vehicle dashboard displays.

For example, various embodiments of the present disclosure provide a display device which may suppress luminance irregularity generated according to a position of a display panel.

Various embodiments of the present disclosure provide a display device in which degradation of visibility of an image in an outer periphery of the display panel is improved.

Technical benefits of the present disclosure are not limited to the above-mentioned benefits, and other benefits, which are not mentioned above, can be clearly understood by those skilled in the art from the following descriptions.

According to an aspect of the present disclosure, a display device comprises a substrate including an active area which includes a first active area and a second active area which encloses the first active area, a light emitting diode which is disposed in the active area and includes an emission area, and an optical member disposed on the light emitting diode, wherein in an upper area or a lower area of the second active area, a center of the optical member is shifted from a center of the emission area.

According to another aspect of the present disclosure, a display device comprises a substrate including an active area which includes a first active area and a second active area which encloses the first active area, a light emitting diode disposed in the active area, and an optical member disposed on the light emitting diode, wherein in the second active area, the closer to outer periphery of the substrate, the smaller width of the optical member.

Other detailed matters of the exemplary embodiments are included in the detailed description and the drawings.

According to the present disclosure, the luminance irregularity which may be generated according to a position of the display panel is improved to uniformize the luminance in the entire area of the display panel.

Further, according to the present disclosure, a phenomenon that an image is not properly recognized but is brightly recognized in an outer peripheral area of the display panel may be improved.

Further, according to the present disclosure, a luminance uniformity in the entire display panel is improved to provide a high quality display image at a lower power.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is an exemplary view of a display device according to an exemplary embodiment of the present disclosure;

FIG. 2 is a functional block diagram of a display device according to an exemplary embodiment of the present disclosure;

FIG. 3 is a schematic plan view of a display device according to an exemplary embodiment of the present disclosure;

FIG. 4 is a circuit diagram illustrating an example of a pixel circuit included in a display device according to an exemplary embodiment of the present disclosure;

FIG. 5 is an enlarged plan view illustrating placement of an optical member included in a first active area of a display device according to an exemplary embodiment of the present disclosure;

FIG. 6 is a cross-sectional view illustrating an example taken along the line VI-VI′ of FIG. 5;

FIG. 7 is a cross-sectional view illustrating an example taken along the line VII-VII′ of FIG. 5;

FIG. 8 is an enlarged plan view illustrating placement of an optical member included in an upper area of a second active area of a display device according to an exemplary embodiment of the present disclosure;

FIG. 9 is a cross-sectional view illustrating an example taken along the line IX-IX′ of FIG. 8;

FIG. 10 is an enlarged plan view illustrating placement of an optical member included in a lower area of a second active area of a display device according to an exemplary embodiment of the present disclosure;

FIG. 11 is a cross-sectional view illustrating an example taken along the line XI-XI′ of FIG. 10;

FIG. 12 is an enlarged plan view illustrating placement of an optical member included in an upper area of a second active area of a display device according to another exemplary embodiment of the present disclosure;

FIG. 13 is an enlarged plan view illustrating placement of an optical member included in a lower area of a second active area of a display device according to another exemplary embodiment of the present disclosure;

FIG. 14 is an enlarged plan view illustrating placement of an optical member included in a left area of a second active area of a display device according to another exemplary embodiment of the present disclosure; and

FIG. 15 is a cross-sectional view illustrating an example taken along lines A-A′ of FIG. 5, B-B′ and C-C′ of FIG. 14.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

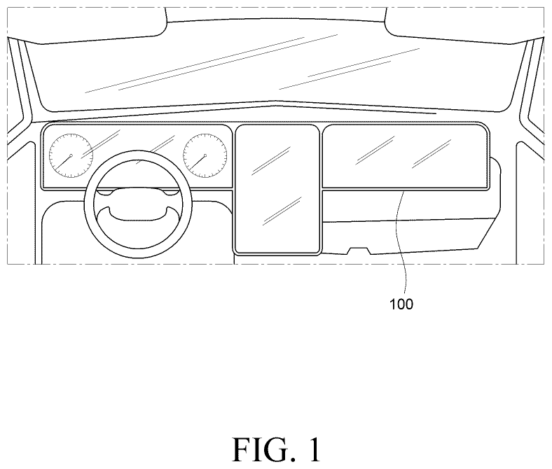

FIG. 1 is an exemplary view of a display device according to an exemplary embodiment of the present disclosure.

Referring to FIG. 1, the display device 100 may be disposed in at least a part of a dash board of a vehicle. The dash board of the vehicle may include a configuration disposed in front surfaces of front seats (for example, a driver seat and a front passenger seat) of the vehicle. For example, on the dash board of the vehicle, an input configuration for manipulating various functions (for example, an air-conditioner, an audio system, or a navigation system) in the vehicle may be disposed.

The display device 100 is disposed on the dash board of the vehicle to operate as an input unit which manipulates at least some of various functions of the vehicle. The display device 100 may provide various information related to the vehicle, for example, operation information of the vehicle (for example, a current speed of the vehicle, a remaining fuel amount, or a mileage) or information about parts of the vehicle (for example, a damage level of a vehicle tire).

The display device 100 may be disposed across the driver seat and the front passenger seat disposed in the front seats of the vehicle. A user of the display device 100 may include a driver of the vehicle and a passenger riding on the front passenger seat. Both the vehicle driver and the passenger may use the display device 100.

Only a part of the display device 100 may be illustrated in FIG. 1. The display device 100 illustrated in FIG. 1 may represent a display panel, among various configurations included in the display device 100. Specifically, for example, the display device 100 illustrated in FIG. 1 may represent at least a part of an active area and a non-active area of the display panel. Among the configurations of the display device 100, configurations other than the parts illustrated in FIG. 1 may be mounted inside the vehicle (or at least a part of the inside of the vehicle).

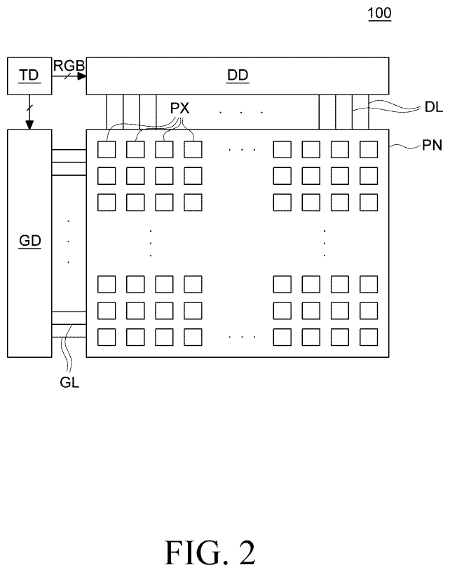

FIG. 2 is a functional block diagram of a display device according to an exemplary embodiment of the present disclosure.

As the display device according to the exemplary embodiment of the present disclosure, an electroluminescent display device may be applied. The electroluminescent display device may use an organic light emitting diode (OLED) display device, a quantum dot light emitting diode display device, or an inorganic light emitting diode display device.

Referring to FIG. 2, the display device 100 may include a display panel PN, a data driving circuit DD, a gate driving circuit GD, and a timing controller TD.

The display panel PN may generate images to be provided to the user. For example, the display panel PN may generate and display images to be provided to the user through a plurality of pixels PX in which the pixel circuits are disposed.

The data driving circuit DD, the gate driving circuit GD, and the timing controller TD may provide signals for operations of each pixel PX through signal lines. For example, signal lines for supplying a signal for operation of each pixel PX may include a plurality of data lines DL and a plurality of gate lines GL.

The plurality of data lines DL is disposed in a column direction and may include a plurality of wiring lines connected to pixels PX disposed in one column direction and the plurality of gate lines GL is disposed in a row direction and may include a plurality of wiring lines connected to pixels PX disposed in one row direction.

In some cases, the display device 100 may further include a power unit. In this case, a signal for an operation of the pixel PX may be supplied through the power line which connects the power unit and the display panel PN. According to the exemplary embodiment, the power unit may supply a power to the data driving circuit DD and the gate driving circuit GD. The data driving circuit DD and the gate driving circuit GD may be driven based on the power supplied from the power unit.

For example, the data driving circuit DD may apply a data signal to each pixel PX through the plurality of data lines DL. The gate driving circuit GD may apply a gate signal to each pixel PX through the plurality of gate lines GL. The power unit may supply a power voltage to each pixel PX through the power voltage supply lines.

The timing controller TD may control the data driving circuit DD and the gate driving circuit GD. For example, the timing controller TD rearranges digital video data input from the outside in accordance with a resolution of the display panel PN to supply the digital video data to the data driving circuit DD.

The data driving circuit DD converts digital video data input from the timing controller TD into an analog data voltage based on the data control signal to supply the converted analog data voltage to the plurality of data lines DL.

The gate driving circuit GD may generate a scan signal and an emission signal based on the gate control signal. For example, the gate driving circuit GD may include a scan driver and an emission signal driver. The scan driver generates a scan signal in a row sequential manner to drive at least one scan line connected to each pixel row to supply the scan signal to the scan lines. The emission signal driver generates an emission signal in a row sequential manner to drive at least one emission signal line connected to each pixel row to supply the emission signal to the emission signal lines.

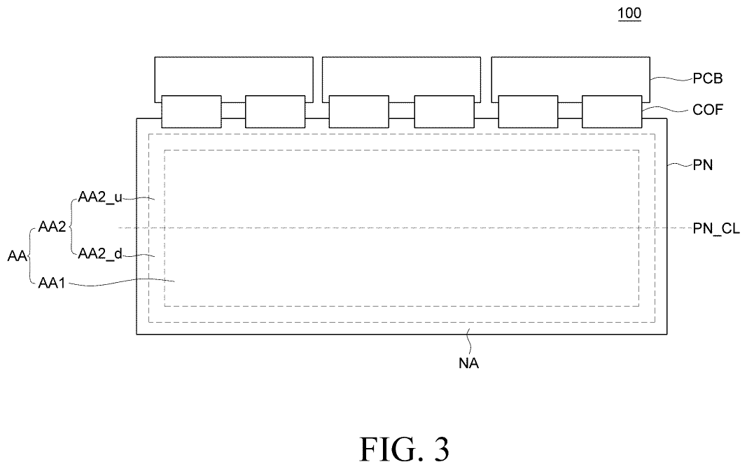

According to the exemplary embodiment, the gate driving circuit GD may be disposed in the display panel PN in a gate-driver in panel (GIP) manner. For example, the gate driving circuit GD is divided into a plurality of circuits to be disposed on at least two side surfaces of the display panel PN. FIG. 3 is a schematic plan view of a display device according to an exemplary embodiment of the present disclosure. For the convenience of description, in FIG. 3, among various components of the display device 100, only a display panel PN, a plurality of flexible films COF, and a printed circuit board PCB are illustrated.

Referring to FIG. 3, the display device 100 according to the exemplary embodiment of the present disclosure includes a display panel PN, a plurality of flexible films COF, and a plurality of printed circuit boards PCB.

The display panel PN includes an active area AA and a non-active area NA.

The active area AA is an area where images are displayed in the display panel PN. The active area AA may include a first active area AA1 including a center portion of the display panel and a second active area AA2 which encloses the first active area AA1. Therefore, the second active area AA2 may be an edge area of the active area AA. Further, the second active area AA2 may include an upper area AA2_u and a lower area AA2_d divided with respect to a center line PN_CL of the display panel PN.

Referring to FIGS. 2 and 3 together, the active area AA of the display panel PN may include a plurality of pixels PX disposed in a row direction and a column direction. For example, the plurality of pixels PX may be disposed in an area where the plurality of data lines DL and the plurality of gate lines GL intersect.

One pixel PX may include a plurality of sub pixels which emits different color light. For example, one pixel PX uses three sub pixels to implement blue, red, and green. However, it is not limited thereto and in some cases, the pixel PX may further include a sub pixel for further implementing a specific color, for example, white.

In the pixel PX, an area which implements blue may be referred to as a blue sub pixel, an area which implements red may be referred to as a red sub pixel, and an area which implements green may be referred to as a green sub pixel.

Each of the plurality of pixels PX may include a first light emitting diode and a second light emitting diode which emit the same color light.

Each of the plurality of pixels PX may include a first optical member which reflects light from the first light emitting diode to a specific direction and a second optical member which reflects light from the second light emitting diode to a specific direction. For example, the first optical member and the second optical member may be implemented as lenses, respectively, but the exemplary embodiment of the present disclosure is not limited thereto.

For example, the first optical member may be disposed in an optical area in which light is provided in a first range to form a first viewing angle and the second optical member may be disposed in an optical area in which light is provided in a second range to form a second viewing angle. The first range may be larger than the second range. Therefore, the first optical member and the second optical member may limit a viewing angle of each of the plurality of pixels PX.

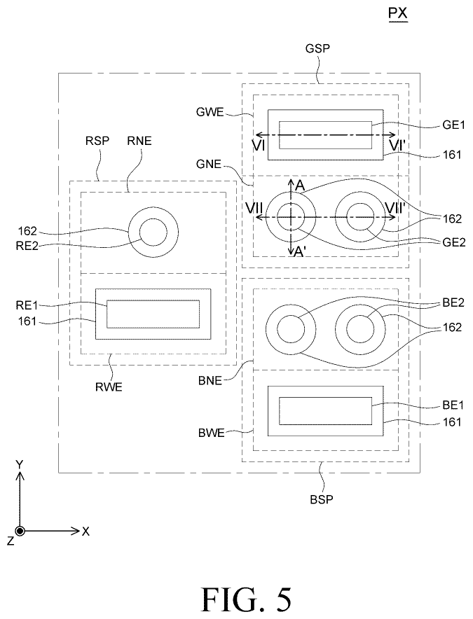

The first optical member and the second optical member will be described in detail below with reference to FIGS. 5 to 11.

The non-active area NA may be disposed along a periphery of the active area AA. For example, the non-active area NA may be an area which encloses the second active area AA2. Various components for driving the pixel circuit disposed in the pixel PX may be disposed in the non-active area NA. For example, at least a part of the gate driving circuit GD may be disposed in the non-active area NA. The non-active area NA may be referred to as a bezel area.

When the display panel PN is used for the vehicle which has been described with reference to FIG. 1, a field of view of at least a partial area of the display panel PN needs to be restricted according to the user's request. For example, images displayed in a region of an active area of the display panel PN which provides an entertainment function and seat information for the passenger sitting on the front passenger seat may interrupt the driving of the driver. Accordingly, according to the user's request, a field of view of the image displayed in the corresponding area needs to be restricted.

Accordingly, each pixel PX included in the display panel PN may be driven in a first mode or a second mode, according to the driving mode. For example, when the pixel PX is driven in the first mode, a first light emitting diode included in a pixel PX emits light based on a selection signal to provide light from the first light emitting diode in a first range through the first optical member, to form a first viewing angle, for example, a wide viewing angle. For example, when the pixel PX is driven in the second mode, a second light emitting diode included in a pixel PX emits light based on a selection signal to provide light from the second light emitting diode in a second range through the second optical member, to form a second viewing angle, for example, a narrow viewing angle. Here, the first mode may correspond to a mode in which the pixel PX is controlled in a wide field-of-view mode (share mode) and the second mode may correspond to a mode in which the pixel PX is driven in a narrow field-of-view mode (private mode).

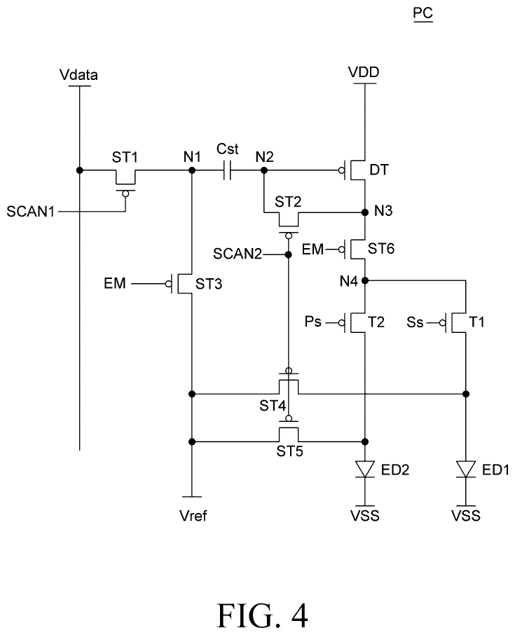

FIG. 4 is a circuit diagram illustrating an example of a pixel circuit included in a display device according to an exemplary embodiment of the present disclosure.

In the meantime, the pixel circuit PC illustrated in FIG. 4 indicates an exemplary embodiment of a pixel circuit corresponding to each of the plurality of pixels PX included in the display device 100 which has been described with reference to FIGS. 2 and 3.

Referring to FIG. 4, at least some of the plurality of transistors included in the pixel circuit PC may be an n-type transistor or a p-type transistor. In the case of the p-type transistor, a low level voltage of each driving signal may refer to a voltage which turns on a TFT and a high level voltage of each driving signal may refer to a voltage which turns off the TFT.

Here, the low level voltage may correspond to a predetermined voltage which is lower than the high level voltage. For example, the low level voltage may include a voltage corresponding to a range of −8 V to −12 V. The high level voltage may correspond to a predetermined voltage which is higher than the low level voltage. For example, the high level voltage may include a voltage corresponding to the range of 12 V to 16 V. According to the exemplary embodiment, the low level voltage may be referred to as a first voltage and the high level voltage may be referred to as a second voltage. In this case, the first voltage may be lower than the second voltage.

The pixel circuit PC may include a driving transistor DT, a plurality of switching transistors ST1 to ST6, a first transistor T1, a second transistor T2, a storage capacitor Cst, and a plurality of light emitting diodes ED1 and ED2.

The driving transistor DT may control a driving current applied to the plurality of light emitting diodes ED1 and ED2 in accordance with a source-gate voltage. The driving transistor DT may include a source electrode connected to a high potential power line which supplies a high potential power voltage VDD, a gate electrode connected to a second node N2, and a drain electrode connected to a third node N3.

The first switching transistor ST1 may apply a data voltage Vdata from the data line DL to a first node N1. The first switching transistor ST1 may include a source electrode connected to the data line DL, a drain electrode connected to the first node N1, and a gate electrode connected to a first scan signal line to which a first scan signal SCAN1 is applied. The first switching transistor ST1 may be turned on or turned off by the first scan signal SCAN1. Accordingly, the first switching transistor ST1 may apply a data voltage Vdata from the data line DL to the first node N1, in response to a low level of first scan signal SCAN1 which is a turn-on level.

The second switching transistor ST2 may diode-connect the gate electrode and the drain electrode of the driving transistor DT. The second switching transistor ST2 may include a drain electrode connected to a second node N2, a source electrode connected to a third node N3, and a gate electrode connected to a second scan signal line to which a second scan signal SCAN2 is applied. The second switching transistor ST2 may be turned on or turned off by the second scan signal SCAN2. Therefore, the second switching transistor ST2 may diode-connect the gate electrode and the drain electrode of the driving transistor DT in response to a low level of second scan signal SCAN2 which is a turn-on level.

The third switching transistor ST3 may apply a reference voltage Vref to the first node N1. The third switching transistor ST3 may include a source electrode which is connected to the reference voltage line which supplies the reference voltage Vref, a drain electrode which is connected to the first node N1, and a gate electrode which is connected to the emission signal line to which the emission signal EM is applied. The third switching transistor ST3 may be turned on or turned off by the emission signal EM. Accordingly, the third switching transistor ST3 may transmit the reference voltage Vref to the first node N1 in response to a low level of emission signal EM which is a turn-on level.

The fourth switching transistor ST4 may apply the reference voltage Vref to the anode electrode of the first light emitting diode ED1. The fourth switching transistor ST4 may include a source electrode connected to the reference voltage line which provides the reference voltage Vref, a drain electrode connected to the anode electrode of the first light emitting diode ED1, and a gate electrode connected to a second scan signal line to which a second scan signal SCAN2 is applied. The fourth switching transistor ST4 may be turned on or turned off by the second scan signal SCAN2. Therefore, the fourth switching transistor ST4 may apply the reference voltage Vref to the anode electrode of the first light emitting diode ED1 in response to the low level of second scan signal SCAN2 which is a turn-on level.

The fifth switching transistor ST5 may apply the reference voltage Vref to the anode electrode of the second light emitting diode ED2. The fifth switching transistor ST5 may include a source electrode connected to the reference voltage line which provides the reference voltage Vref, a drain electrode connected to the anode electrode of the second light emitting diode ED2, and a gate electrode connected to a second scan signal line to which a second scan signal SCAN2 is applied. The fifth switching transistor ST5 may be turned on or turned off by the second scan signal SCAN2. Therefore, the fifth switching transistor ST5 may apply the reference voltage Vref to the anode electrode of the second light emitting diode ED2 in response to the low level of second scan signal SCAN2 which is a turn-on level.

The sixth switching transistor ST6 may form a current path between the driving transistor DT and any one light emitting diode among the plurality of light emitting diodes ED1 and ED2. The sixth switching transistor ST6 may include a source electrode connected to the third node N3, a drain electrode connected to the fourth node N4, and a gate electrode connected to the emission signal line to which an emission signal EM is applied. The sixth switching transistor ST6 may be turned on or turned off by the emission signal EM. Therefore, the sixth switching transistor ST6 electrically connects the third node N3 and the fourth node N4 in response to a low level of emission signal EM which is a turn-on level to form a current path between the driving transistor DT and any one light emitting diode among the plurality of light emitting diodes ED1 and ED2.

The storage capacitor Cst may include a first electrode connected to the first node N1 and a second electrode connected to the second node N2. One electrode of the storage capacitor Cst may be connected to the gate electrode of the driving transistor DT and the other electrode of the storage capacitor Cst may be connected to the first switching transistor ST1. The storage capacitor Cst stores a predetermined voltage to constantly maintain a voltage of the gate electrode of the driving transistor DT while any one of the plurality of light emitting diodes ED1 and ED2 emits light.

The first transistor T1 may generate a current path of a first driving current which passes through the first light emitting diode ED1 and the second transistor T2 may generate a current path of a second driving current which passes through the second light emitting diode ED2.

The first transistor T1 may be connected between the fourth node N4 and the first light emitting diode ED1 and a gate electrode of the first transistor T1 may be connected to a first selection signal line which supplies a first selection signal Ss. When the pixel PX to which the pixel circuit PC is applied is driven in a first mode which is a wide field-of-view mode, the first selection signal Ss is supplied to the gate electrode of the first transistor T1 to turn on the first transistor T1. Therefore, a current path of the first driving current which passes through the first light emitting diode ED1 is formed so that the first light emitting diode ED1 may emit light. In the meantime, the first transistor T1 may be referred to as a first emission control transistor which controls emission of the first light emitting diode ED1.

The second transistor T2 may be connected between the fourth node N4 and the second light emitting diode ED2 and a gate electrode of the second transistor T2 may be connected to a second selection signal line which supplies a second selection signal Ps. When the pixel PX to which the pixel circuit PC is applied is driven in a second mode which is a narrow field-of-view mode, the second selection signal Ps is supplied to the gate electrode of the second transistor T2 to turn on the second transistor T2. Therefore, a current path of the second driving current which passes through the second light emitting diode ED2 is formed so that the second light emitting diode ED2 may emit light. In the meantime, the second transistor T2 may be referred to as a second emission control transistor which controls emission of the second light emitting diode ED2.

The first light emitting diode ED1 may be connected between the first transistor T1 which is turned on or turned off by the first selection signal Ss and the low potential power line which supplies a low potential power voltage VSS. The second light emitting diode ED2 may be connected between the second transistor T2 which is turned on or turned off by the second selection signal Ps and the low potential power line which supplies a low potential power voltage VSS.

In this case, the first light emitting diode ED1 or the second light emitting diode ED2 may be connected to another configuration of the pixel circuit PC, for example, the driving transistor DT, by the first transistor T1 or the second transistor T2 which is turned on according to a driving mode. For example, the first light emitting diode ED1 may be connected to the driving transistor DT via the first transistor T1 which is turned on in the first mode and may supply light by the first driving current, in the first mode, that is, in the wide field-of-view mode at a wide viewing angle which is a first viewing angle. Further, the second light emitting diode ED2 may be connected to the driving transistor DT via the second transistor T2 which is turned on in the second mode and may supply light by the second driving current, in the second mode, that is, in the narrow field-of-view mode at a narrow viewing angle which is a second viewing angle. Here, the driving mode may be specified by the user's input or determined when a predetermined condition is satisfied.

In the first mode, only the first light emitting diode ED1 may emit light and in the second mode, only the second light emitting diode ED2 may emit light. Here, the second selection signal Ps which controls the emission of the second light emitting diode ED2 may be output only at a high level which is a turn-off level to allow only the first light emitting diode ED1 to emit light in the first mode. Further, the first selection signal Ss which controls the emission of the first light emitting diode ED1 may be output only at a high level which is a turn-off level to allow only the second light emitting diode ED2 to emit light in the second mode.

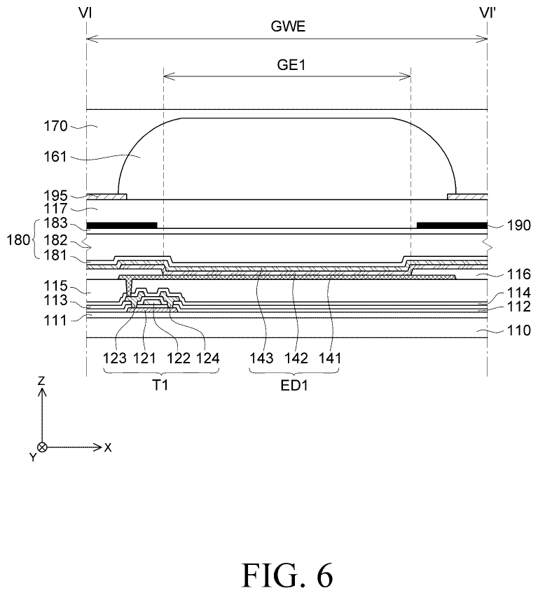

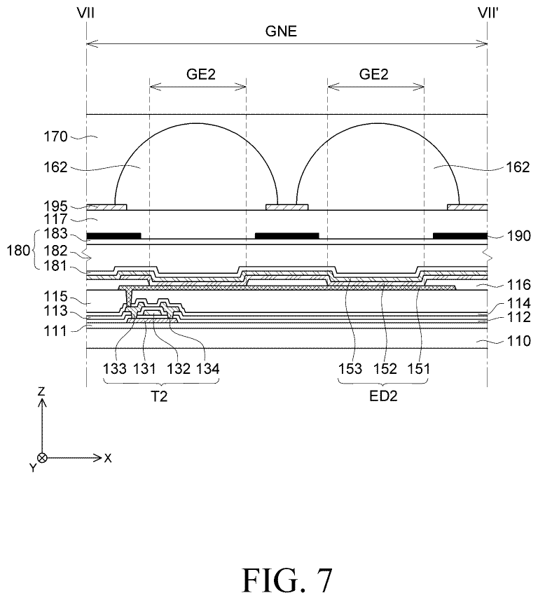

FIG. 5 is an enlarged plan view illustrating placement of an optical member included in a first active area of a display device according to an exemplary embodiment of the present disclosure. FIG. 6 is a cross-sectional view illustrating an example taken along the line VI-VI′ of FIG. 5. FIG. 7 is a cross-sectional view illustrating an example taken along the line VII-VII′ of FIG. 5.

In the meantime, FIG. 5 illustrates a plane of a pixel PX when the pixel PX includes three sub pixels, for example, a first sub pixel RSP, a second sub pixel GSP, and a third sub pixel BSP.

Further, FIG. 6 illustrates a pixel in which a first optical member 161 is disposed as an exemplary embodiment of a display device 100 taken along the line VI-VI′ of FIG. 5. FIG. 7 illustrates a pixel in which a second optical member 162 is disposed as an exemplary embodiment of a display device 100 taken along the line VII-VII′ of FIG. 5.

In the meantime, in FIGS. 6 and 7, for the convenience of description, only a region corresponding to a first optical area GWE and a second optical area GNE of the second sub pixel GSP, among three sub pixels RSP, GSP, and BSP illustrated in FIG. 5, is illustrated. However, the other sub pixels RSP and BSP may also be formed with the same configuration.

In the meantime, for the convenience of description, hereinafter, a horizontal direction on the plain is illustrated as a first direction X and a vertical direction on the plane is illustrated as a second direction Y. Further, a normal direction of a plane defined by the first direction X and the second direction Y, for example, a thickness direction of the display device 100 may be defined as a third direction Z.

Referring to FIG. 5, the pixel PX may include a plurality of sub pixels RSP, GSP, and BSP which represents different colors. For example, the pixel PX may include a first sub pixel RSP which implements red, a second sub pixel GSP which implements green, and a third sub pixel BSP which implements blue. According to the exemplary embodiment, a first sub pixel RSP may be referred to as a red sub pixel, a second sub pixel GSP may be referred to as a green sub pixel, and a third sub pixel BSP may be referred to as a blue sub pixel. In each of the plurality of sub pixels RSP, GSP, and BSP included in the pixel PX, the pixel circuit PC which has been described with reference to FIG. 3 may be disposed.

The plurality of sub pixels RSP, GSP, and BSP may include first optical areas RWE, GWE, and BWE and second optical areas RNE, GNE, and BNE which provide different viewing angles, respectively.

The first optical areas RWE, GWE, and BWE of the sub pixels RSP, GSP, and BSP may operate independently from the second optical areas RNE, GNE, and BNE of the corresponding pixels PX. For example, each sub pixel RSP, GSP, BSP may include a first light emitting diode ED1 disposed in the first optical area RWE, GWE, BWE of a corresponding sub pixel RSP, GSP, BSP and a second light emitting diode ED2 disposed in the second optical area RNE, GNE, BNE of a corresponding sub pixel RSP, GSP, BSP.

In one pixel PX, the first light emitting diode ED1 and the second light emitting diode ED2 may be disposed in every first optical area RWE, GWE, BWE and every second optical areas RNE, GNE, BNE of the plurality of sub pixels RSP, GSP, and BSP, respectively.

For example, in one pixel PX, a first light emitting diode ED1 disposed in the first optical area RWE of the first sub pixel RSP, a second light emitting diode ED2 disposed in the second optical area RNE of the first sub pixel RSP, a first light emitting diode ED1 disposed in the first optical area GWE of the second sub pixel GSP, a second light emitting diode ED2 disposed in the second optical area GNE of the second sub pixel GSP, a first light emitting diode ED1 disposed in the first optical area BWE of the third sub pixel BSP, and a second light emitting diode ED2 disposed in the second optical area BNE of the third sub pixel BSP may be disposed.

Referring to FIG. 5, in the first optical area RWE, GWE, BWE of each sub pixel RSP, GSP, BSP, at least one first optical member 161 disposed so as to overlap the first emission area RE1, GE1, BE1 of the first light emitting diode ED1 may be disposed. In the second optical area RNE, GNE, BNE of each sub pixel RSP, GSP, BSP, at least one second optical member 162 disposed so as to overlap the second emission area RE2, GE2, BE2 of the second light emitting diode ED2 may be disposed. At this time, the first optical areas RWE, GWE, and BWE may have a first viewing angle and the second optical areas RNE, GNE, and BNE may have a second viewing angle which is smaller than the first viewing angle.

Referring to FIGS. 5 to 7 together, the display device 100 according to the exemplary embodiment of the present disclosure may include a substrate 110, a buffer film 111, a gate insulating film 112, a first interlayer insulating film 113, a lower protection film 114, an overcoat layer 115, a bank 116, a first transistor T1, a second transistor T2, a first light emitting diode ED1, a second light emitting diode ED2, an encapsulation member 180, a second interlayer insulating film 117, a black matrix 190, a barrier layer 195, a first optical member 161, a second optical member 162, and an optical member protection film 170.

The substrate 110 may include an insulating material. The substrate 110 may include a transparent material. For example, the substrate 110 may include glass or plastic.

The buffer film 111 may be disposed on the substrate 110. The buffer film 111 may include an insulating material. For example, the buffer film 111 may include an inorganic insulating material, such as silicon oxide (SiOx) or silicon nitride (SiNx). The buffer film 111 may have a multi-layered structure. For example, the buffer film 111 may have a laminated structure of a film formed of silicon nitride (SiNx) and a film formed of silicon oxide (SiOx).

The buffer film 111 may be located between the substrate 110 and a driving part of each sub pixel RSP, GSP, BSP. The buffer film 111 may suppress the contamination due to the substrate 110 in a process of forming the driving part. For example, a top surface of the substrate 110 which faces the driving part of each sub pixel RSP, GSP, BSP may be covered by the buffer film 111. The driving part of each sub pixel RSP, GSP, BSP may be disposed on the buffer film 111.

The gate insulating film 112 may be disposed on the buffer film 111. The gate insulating film 112 may include an insulating material. For example, the gate insulating film 112 may include an inorganic insulating material, such as silicon oxide (SiO) or silicon nitride (SiN). The gate insulating film 112 may include a material having a high permittivity. For example, the gate insulating film 112 may include a High-K material, such as hafnium oxide (HfO). The gate insulating film 112 may have a multi-layered structure.

The first interlayer insulating film 113 may be disposed on the gate insulating film 112. The first interlayer insulating film 113 may include an insulating material. For example, the first interlayer insulating film 113 may include an inorganic insulating material, such as silicon oxide (SiO) or silicon nitride (SiN). The first interlayer insulating film 113 may extend between the gate electrodes 122 and 132 and the source electrodes 123 and 133 of the transistors T1 and T2 and between the gate electrodes 122 and 132 and the drain electrodes 124 and 134. For example, the source electrodes 123 and 133 and the drain electrodes 124 and 134 of the first transistor T1 and the second transistor T2 may be insulated from the gate electrodes 122 and 132 by the first interlayer insulating film 113. The first interlayer insulating film 113 may cover the gate electrodes 122 and 132 of the first transistor T1 and the second transistor T2. The source electrodes 123 and 133 and the drain electrodes 124 and 134 of each sub pixel RSP, GSP, BSP may be located on the first interlayer insulating film 113. The gate insulating film 112 and the first interlayer insulating film 113 may expose a source region and a drain region of each semiconductor layer 121, 131 located in each sub pixel RSP, GSP, BSP.

The lower protection film 114 may be disposed on the first interlayer insulating film 113. The lower protection film 114 may include an insulating material. For example, the lower protection film 114 may include an inorganic insulating material, such as silicon oxide (SiO) or silicon nitride (SiN).

The lower protection film 114 may suppress the damage of the driving part due to the external moisture and shocks. The lower protection film 114 may extend along surfaces of the first transistor T1 and the second transistor T2. The lower protection film 114 may be in contact with the first interlayer insulating film 113 at the outside of the driving part located in each sub pixel RSP, GSP, BSP.

The overcoat layer 115 may be disposed on the lower protection film 114. The overcoat layer 115 may include an insulating material. The overcoat layer 115 may include a material different from that of the lower protection film 114. For example, the overcoat layer 115 may include an organic insulating material.

The overcoat layer 115 may remove a step caused by the driving part of each sub pixel RSP, GSP, BSP. For example, a top surface of the overcoat layer 115 which is opposite to the substrate 110 may be a flat surface.

The first transistor T1 and the second transistor T2 may be disposed on the substrate 110. The first transistor T1 may be electrically connected between the drain electrode of the driving transistor DT and the first lower electrode 141 of the first light emitting diode ED1. The second transistor T2 may be electrically connected between the drain electrode of the driving transistor DT and the second lower electrode 151 of the second light emitting diode ED2.

The first transistor T1 may include a first semiconductor layer 121, a first gate electrode 122, a first source electrode 123, and a first drain electrode 124. The first transistor T1 may have the same structure as the switching transistor and the driving transistor.

For example, the first semiconductor layer 121 may be located between the buffer film 111 and the gate insulating film 112 and the first gate electrode 122 may be located between the gate insulating film 112 and the first interlayer insulating film 113. The first source electrode 123 and the first drain electrode 124 may be located between the first interlayer insulating film 113 and the lower protection film 114. The first gate electrode 122 may overlap a channel region of the first semiconductor layer 121. The first source electrode 123 may be electrically connected to the source region of the first semiconductor layer 121. The first drain electrode 124 may be electrically connected to the drain region of the first semiconductor layer 121.

The second transistor T2 may include a second semiconductor layer 131, a second gate electrode 132, a second source electrode 133, and a second drain electrode 134. For example, the second semiconductor layer 131 may be located on the same layer as the first semiconductor layer 121 and the second gate electrode 132 may be located on the same layer as the first gate electrode 122. The second source electrode 133 and the second drain electrode 134 may be located on the same layer as the first source electrode 123 and the first drain electrode 124.

The first light emitting diode ED1 and the second light emitting diode ED2 of each sub pixel RSP, GSP, BSP may be located on the overcoat layer 115 of each sub pixel RSP, GSP, BSP. For example, the first lower electrode 141 of the first light emitting diode ED1 may be electrically connected to the first drain electrode 124 or the first source electrode 123 of the first transistor T1 through a contact hole which passes through the lower protection film 114 and the overcoat layer 115. A second lower electrode 151 of the second light emitting diode ED2 may be electrically connected to the second drain electrode 134 or the second source electrode 133 of the second transistor T2 through a contact hole which passes through the lower protection film 114 and the overcoat layer 115.

The first light emitting diode ED1 may emit light representing a specific color. For example, the first light emitting diode ED1 may include a first lower electrode 141, a first emission layer 142, and a first upper electrode 143 which are sequentially laminated on the substrate 110.

The first lower electrode 141 may include a conductive material. The first lower electrode 141 may include a material having a high reflectance. For example, the first lower electrode 141 may include metal, such as aluminum (Al), and silver (Ag). The first lower electrode 141 may have a multi-layered structure. For example, the first lower electrode 141 may have a structure in which a reflective electrode formed of a metal is located between transparent electrodes formed of a transparent conductive material, such as ITO and IZO. The first lower electrode 141 may be electrically connected to the first drain electrode 124 or the first source electrode 123 of the first transistor T1 through a contact hole which passes through the lower protection film 114 and the overcoat layer 115.

The first emission layer 142 may generate light with luminance corresponding to a voltage difference between the first lower electrode 141 and the first upper electrode 143. For example, the first emission layer 142 may include an emission material layer (EML) including an emission material. The emission material may include an organic material, an inorganic material, or a hybrid material.

The first emission layer 142 may have a multi-layered structure. For example, the first emission layer 142 may further include at least one of a hole injection layer HIL, a hole transport layer HTL, an electron transport layer ETL, and an electron injection layer EIL.

The first upper electrode 143 may include a conductive material. The first upper electrode 143 may include a different material from that of the first lower electrode 141. A transmittance of the first upper electrode 143 may be higher than a transmittance of the first lower electrode 141. For example, the first upper electrode 143 may be a transparent electrode formed of a transparent conductive material, such as ITO and IZO. Accordingly, in the display device 100 according to the exemplary embodiment of the present disclosure, light generated by the first emission layer 142 may be emitted through the first upper electrode 143.

The second light emitting diode ED2 may implement the same color as the first light emitting diode ED1 disposed in the same sub pixel RSP, GSP, BSP. For example, the second light emitting diode ED2 may include a second lower electrode 151, a second emission layer 152, and a second upper electrode 153 which are sequentially laminated on the substrate 110.

The second lower electrode 151 may correspond to the first lower electrode 141, the second emission layer 152 may correspond to the first emission layer 142, and the second upper electrode 153 may correspond to the first upper electrode 143. For example, the second lower electrode 151 may be formed for the second light emitting diode ED2 with the same structure as the first lower electrode 141 and this is the same for the second emission layer 152 and the second upper electrode 153. For example, the first light emitting diode ED1 and the second light emitting diode ED2 may be formed to have the same structure. However, it is not limited thereto and in some cases, at least a partial configuration of the first light emitting diode ED1 and the second light emitting diode ED2 may be formed to be different.

The second emission layer 152 may be spaced apart from the first emission layer 142. Therefore, in the display device according to the exemplary embodiment of the present disclosure, light emission by a leakage current may be suppressed.

According to the exemplary embodiment of the present disclosure, in the display device, light may be generated by only one of the first emission layer 142 and the second emission layer 152 by the user's choice or according to a predetermined condition.

The second lower electrode 151 of each sub pixel RSP, GSP, BSP may be spaced apart from the first lower electrode 141 of the corresponding sub pixel RSP, GSP, BSP. For example, the bank 116 may be disposed between the first lower electrode 141 and the second lower electrode 151 of each sub pixel RSP, GSP, BSP. The bank 116 may include an insulating material. For example, the bank 116 may include an organic insulating material. The bank 116 may include a material different from that of the overcoat layer 115.

The second lower electrode 151 of each sub pixel RSP, GSP, BSP may be insulated from the first lower electrode 141 of the corresponding sub pixel RSP, GSP, BSP by the bank 116. For example, the bank 116 may cover an edge of the first lower electrode 141 and an edge of the second lower electrode 151 located in each sub pixel RSP, GSP, BSP.

The bank 116 may divide the first emission areas RE1, GE1, and BE1 of the first light emitting diode ED1 and the second emission areas RE2, GE2, and BE2 of the second light emitting diode ED2. For example, the first emission areas RE1, GE1, and BE1 of the first light emitting diode ED1 may be a partial area of the first lower electrode 141 which is exposed by the bank 116. The second emission areas RE2, GE2, and BE2 of the second light emitting diode ED2 may be a partial area of the second lower electrode 151 which is exposed by the bank 116. At this time, referring to FIG. 5, a size of the first emission areas RE1, GE1, and BE1 of the first light emitting diode ED1 divided in each sub pixel RSP, GSP, BSP may be larger than a size of the second emission areas RE2, GE2, and BE2 of the second light emitting diode ED2, but is not limited thereto.

The first emission layer 142 and the first upper electrode 143 of the first light emitting diode ED1 located in each sub pixel RSP, GSP, BSP may be laminated on a partial area of the first lower electrode 141 exposed by the bank 116. Specifically, the first emission layer 142 and the first upper electrode 143 may be laminated on the first emission areas RE1, GE1, BE1 exposed by the bank 116 and the bank 116. The second emission layer 152 and the second upper electrode 153 of the second light emitting diode ED2 located in each sub pixel RSP, GSP, BSP may be laminated on a partial area of the second lower electrode 151 exposed by the bank 116. Specifically, the second emission layer 152 and the second upper electrode 153 may be laminated on the second emission areas RE2, GE2, and BE2 exposed by the bank 116 and the bank 116.

The second upper electrode 153 of each sub pixel RSP, GSP, BSP may be electrically connected to the first upper electrode 143 of the corresponding sub pixel RSP, GSP, BSP. For example, a voltage applied to the second upper electrode 153 of the second light emitting diode ED2 located in each sub pixel RSP, GSP, BSP may be equal to a voltage applied to the first upper electrode 143 of the first light emitting diode ED1 located in the corresponding sub pixel RSP, GSP, BSP. The second upper electrode 153 of each sub pixel RSP, GSP, BSP may include the same material as the first upper electrode 143 of the corresponding sub pixel RSP, GSP, BSP. For example, the second upper electrode 153 of each sub pixel RSP, GSP, BSP may be formed simultaneously with the first upper electrode 143 of the corresponding sub pixel RSP, GSP, BSP. The second upper electrode 153 of each sub pixel RSP, GSP, BSP extends onto the bank 116 to be in direct contact with the first upper electrode 143 of the corresponding sub pixel RSP, GSP, BSP. Luminance of the first optical areas RWE, GWE, and BWE and luminance of the second optical areas RNE, GNE, and BNE located in each sub pixel RSP, GSP, BSP may be controlled by a driving current generated in the corresponding sub pixel RSP, GSP, BSP.

The encapsulation member 180 may be located on the first light emitting diode ED1 and the second light emitting diode ED2 of each sub pixel RSP, GSP, BSP. The encapsulation member 180 may suppress the damage of the light emitting diodes ED1 and ED2 due to moisture and shocks from the outside. The encapsulation member 180 may have a multi-layered structure. For example, the encapsulation member 180 may include a first encapsulation layer 181, a second encapsulation layer 182, and a third encapsulation layer 183 which are sequentially laminated, but the exemplary embodiments of the present disclosure are not limited thereto.

The first encapsulation layer 181, the second encapsulation layer 182, and the third encapsulation layer 183 may include an insulating material. The second encapsulation layer 182 may include a material different from those of the first encapsulation layer 181 and the third encapsulation layer 183. For example, the first encapsulation layer 181 and the third encapsulation layer 183 are inorganic encapsulation layers including an inorganic insulating material and the second encapsulation layer 182 may include an organic encapsulation layer including an organic insulating material. Therefore, the damage of the light emitting diodes ED1 and ED2 of the display device 100 due to the moisture and shocks from the outside may efficiently suppress. As described above, when the second encapsulation layer 182 includes an organic insulating material, due to the flowing nature of the organic insulting material, a height thereof may decrease toward an outer periphery of the display panel PN. For example, in the first active area AA1, the height of the second encapsulation layer 182 may be uniformly maintained, but in the second active area AA2, the height of the second encapsulation layer 182 may decrease toward the outer periphery. Therefore, in the second active area AA2, maximum heights of the first optical member 161 and the second optical member 162 which are disposed above the second encapsulation layer 182 may also decrease toward the outer periphery.

The black matrix 190 may be disposed on the encapsulation member 180. The black matrix 190 may be disposed between the plurality of sub pixels RSP, GSP, and BSP so as to reduce color mixture of the plurality of sub pixels RSP, GSP, and BSP. Therefore, the black matrix 190 may be disposed so as to overlap the bank 116.

The second interlayer insulating film 117 may be disposed on the black matrix 190. The second interlayer insulating film 117 is disposed between the encapsulation member 180, the black matrix 190 and the barrier layer 195 to insulate the barrier layer 195.

The second interlayer insulating film 117 may include an insulating material. For example, the second interlayer insulating film 117 may include an organic insulating material or an inorganic insulating material, but is not limited thereto.

A plurality of barrier layers 195 may be disposed on the second interlayer insulating film 117. The plurality of barrier layers 195 may be disposed above the first light emitting diode ED1 and the second light emitting diode ED2 in the active area. The plurality of barrier layers 195 may be disposed so as to be spaced apart from each other on the second interlayer insulating film 117.

The plurality of barrier layers 195 may be disposed so as to overlap the bank 116 and the black matrix 190. The plurality of barrier layers 195 may limit a path of light generated by the first light emitting diode ED1 and the second light emitting diode ED2. For example, the plurality of barrier layers 195 may block light which travels to the lateral direction, among light emitted from the first emission areas RE1, GE1, and BE1 and the second emission areas RE2, GE2, and BE2. That is, the plurality of barrier layers 195 may block light which travels to the lateral direction, among light emitted from the first emission areas RE1, GE1, and BE1 and the second emission areas RE2, GE2, and BE2 located in each sub pixel RSP, GSP, BSP, together with the first optical member 161 and the second optical member 162.

The plurality of barrier layers 195 may be formed of the same material as the plurality of touch electrodes. For example, the plurality of barrier layers 195 may include a metal material, such as titanium (Ti), aluminum (Al), silver (Ag), copper (Cu), and a magnesium-silver alloy (Mg:Ag), but is not limited thereto.

In the meantime, a touch buffer layer may be further disposed between the encapsulation member 180 and the barrier layer 195, but is not limited thereto.

Even though it is not illustrated in the drawing, a plurality of touch electrodes may be disposed on the second interlayer insulating film 117. The plurality of touch electrodes may be configured to sense an external touch input using a user's finger or a touch pen. At this time, the plurality of barrier layers 195 may be disposed on the same layer as the touch electrode, but is not limited thereto. Further, a touch bridge electrode may be further disposed on the encapsulation member 180 in addition to the touch electrode, but is not limited thereto.

The first optical member 161 and the second optical member 162 may be disposed on the second interlayer insulating film 117.

The first optical member 161 and the second optical member 162 may be disposed on the same layer as the plurality of barrier layers 195 on the second interlayer insulating film 117. For example, the first optical member 161 and the second optical member 162 may be disposed so as to cover edges of the plurality of barrier layers 195. Therefore, an end of each of the first optical member 161 and the second optical member 162 may be disposed on the plurality of barrier layers 195.

At this time, a center of the first optical member 161 may match a center of the first emission area RE1, GE1, BE1. Further, a center of the second optical member 162 may match a center of the second emission area RE2, GE2, BE2.

First, referring to FIG. 6, the first optical member 161 may be disposed on the first light emitting diode ED1. Light generated by the first light emitting diode ED1 of each sub pixel RSP, GSP, BSP may be emitted through the first optical member 161 disposed in the first optical area RWE, GWE, BWE of the corresponding sub pixel RSP, GSP, BSP.

The first optical member 161 has a shape which does not restrict the light to traveling in at least one direction. In the present disclosure, a planar shape of the first optical member 161 located in each sub pixel RSP, GSP, BSP may have a shape which extends in the first direction X. For example, a planar shape of the first optical member 161 may have a bar shape extending in the first direction X. Therefore, the planar shape of the first optical member 161 may include a long side extending in the first direction X and a short side which is connected from both ends of the long side in the second direction Y. For example, a planar shape of the first optical member 161 may be a rectangle with a long side placed in the first direction X.

In this case, a traveling direction of light emitted from the first optical area RWE, GWE, BWE of each sub pixel RSP, GSP, BSP may not be limited in the first direction X. For example, contents (or images) provided through the first optical area RWE, GWE, BWE of each sub pixel RSP, GSP, BSP may be shared by surrounding people which are adjacent to the user in the first direction X. Accordingly, the contents provided by the light emitted through the first optical member 161 may be provided at a viewing angle which is larger in the first direction X than contents provided by the light emitted through the second optical member 162. For example, the content provided by the light emitted through the first optical member 161 may be provided in a wide field-of-view mode (share mode).

At least a part of a top surface of a cross-sectional shape of the first optical member 161 taken along the first direction X may be flat. Further, both side surfaces of the first optical member 161 may be formed as a curved line or a straight line. For example, referring to FIG. 6, a cross-sectional shape with respect to the long side of the first optical member 161 may be formed by an upper flat surface and a curved line which is connected from both ends of the flat surface toward the second interlayer insulating film 117. Alternatively, for example, a cross-sectional shape with respect to the long side of the first optical member 161 may be formed by an upper flat surface and a straight line which is vertically connected from both ends of the flat surface toward the second interlayer insulating film 117.

Next, referring to FIG. 7, the second optical member 162 may be disposed on the second light emitting diode ED2. Light generated by the second light emitting diode ED2 of each sub pixel RSP, GSP, BSP may be refracted through the second optical member 162 disposed in the second optical area RNE, GNE, BNE of a corresponding sub pixel RSP, GSP, BSP to be emitted. The second optical member 162 may limit the traveling of the passing light in the first direction X. For example, a planar shape of the second optical member 162 located in each sub pixel RSP, GSP, BSP may be a circular shape. However, it is not limited thereto and a planar shape of the second optical member 162 located in each sub pixel RSP, GSP, BSP may be a polygonal shape.

In this case, traveling of light emitted from the second optical area RNE, GNE, BNE of each sub pixel RSP, GSP, BSP in the first direction X may be limited. For example, the contents (or images) provided by the second optical areas RNE, GNE, BNE of each sub pixel RSP, GSP, BSP may not be shared by the people around the user. Accordingly, the contents provided by the light emitted through the second optical member 162 may be provided at a viewing angle which is smaller in the left and right than the contents provided by the light emitted through the first optical member 161. For example, the contents provided by the light emitted through the second optical member 162 may be provided in a narrow field-of-view mode (private mode).

A cross-sectional shape of the second optical member 162 taken along the first direction X may be a semicircular shape, but is not limited thereto. The first emission area RE1, GE1, BE1 of each pixel PX may have a shape corresponding to the first optical member 161 of the corresponding sub pixel RSP, GSP, BSP. For example, a planar shape of the first emission area RE1, GE1, BE1 of each sub pixel RSP, GSP, BSP may have a bar shape which extends in the first direction X. The first optical member 161 may have a size larger than the first emission area RE1, GE1, BE1 of the corresponding sub pixel RSP, GSP, BSP. Accordingly, efficiency of light emitted from the first emission area RE1, GE1, BE1 of each sub pixel RSP, GSP, BSP may be improved.

The second emission area RE2, GE2, BE2 of each sub pixel RSP, GSP, BSP may have a shape corresponding to the second optical member 162 of the corresponding sub pixel RSP, GSP, BSP. For example, a planar shape of the second emission area RE2, GE2, BE2 of each sub pixel RSP, GSP, BSP may be a circular shape or a polygonal shape. The second optical member 162 may have a size larger than the second emission area RE2, GE2, BE2 of the corresponding sub pixel RSP, GSP, BSP. Accordingly, efficiency of light emitted from the second emission area RE2, GE2, BE2 of sub pixel RSP, GSP, BSP may be improved.

The number of second emission areas RE2, GE2, and BE2 may vary in each sub pixel RSP, GSP, BSP. For example, the number of second emission areas GE2 defined in the second optical area GNE of the second sub pixel GSP and the number of second emission areas BE2 defined in the second optical area BNE of the third sub pixel BSP may be larger than the number of second emission areas RE2 defined in the second optical area RNE of the first sub pixel RSP. In this case, the efficiency deviation of the second light emitting diodes ED2 located on each second optical area RNE, GNE, BNE may be compensated by the number of second emission areas RE2, GE2, and BE2 defined in the second optical area RNE, GNE, BNE of each sub pixel RSP, GSP, BSP.

The optical member protection film 170 may be located on the first optical member 161 and the second optical member 162 of the sub pixels RSP, GSP, and BSP. The optical member protection film 170 may include an insulating material. For example, the optical member protection film 170 may include an organic insulating material. A refractive index of the optical member protection film 170 may be smaller than a refractive index of the first optical member 161 and a refractive index of the second optical member 162 located in each sub pixel RSP, GSP, BSP. Accordingly, in the display device 100 according to the exemplary embodiment of the present disclosure, light which passes through the first optical member 161 and the second optical member 162 in each sub pixel RSP, GSP, BSP may not be reflected toward the substrate 110 due to the refractive index difference from the optical member protection film 170.

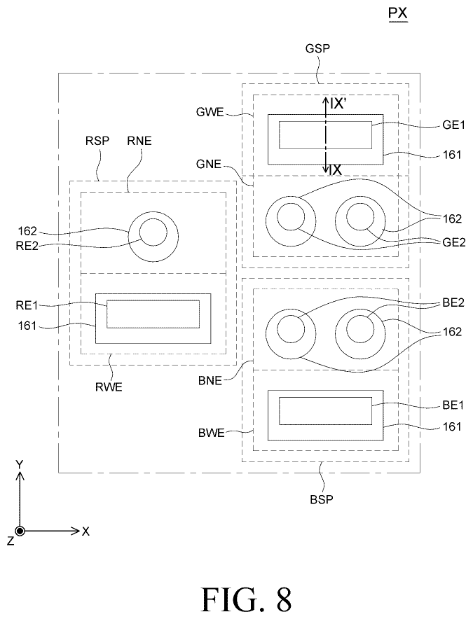

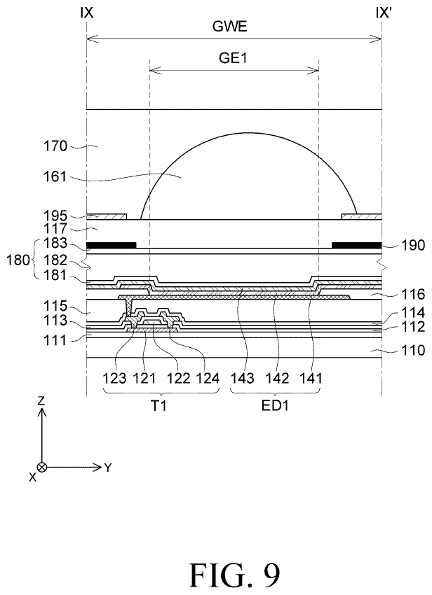

FIG. 8 is an enlarged plan view illustrating placement of an optical member included in an upper area of a second active area of a display device according to an exemplary embodiment of the present disclosure. FIG. 9 is a cross-sectional view illustrating an example taken along the line IX-IX′ of FIG. 8.

Specifically, FIG. 8 is an enlarged plan view of an upper area AA2_u with respect to a panel center line PN_CL in the second active area AA2 of the display device 100 according to the exemplary embodiment of the present disclosure. Further, FIG. 9 is a cross-sectional view illustrating a cross-section with respect to a short side of the first optical member 161 disposed in the upper area AA2_u of the second active area AA2.

All configurations of the upper area AA2_u of the second active area AA2 of FIGS. 8 and 9 are the same as the first active area AA1 of FIGS. 5 to 7 except positions of the first optical member 161 and the second optical member 162, so that a redundant description will be omitted.

Referring to FIGS. 8 and 9, in the upper area AA2_u of the second active area AA2, the first optical member 161 is shifted from the center of the first emission area RE1, GE1, BE1 to one side. Further, the second optical member 162 is also shifted from the center of the second emission area RE2, GE2, BE2 to one side.

Specifically, in the upper area AA2_u of the second active area AA2, the first optical member 161 and the second optical member 162 may be shifted to the same direction. For example, in the upper area AA2_u of the second active area AA2, a direction in which the first optical member 161 is shifted from the center of the first emission area RE1, GE1, BE1 and a direction in which the second optical member 162 is shifted from the center of the second emission area RE2, GE2, BE2 may be the same. That is, both the first optical member 161 and the second optical member 162 disposed in the upper area AA2_u of the second active area AA2 may be shifted to the same direction regardless of the positions.

For example, referring to FIG. 8, in the upper area AA2_u of the second active area AA2, the first optical member 161 may be shifted downwardly from the center of the first emission area RE1, GE1, BE1. In this case, the second optical member 162 located in the upper area AA2_u of the second active area AA2 may also be shifted toward the lower direction of the display panel PN, as illustrated in FIG. 8. Therefore, both the first optical member 161 and the second optical member 162 disposed in the upper area AA2_u of the second active area AA2 may be shifted to the lower direction of the display panel PN.

As described above, when the first emission areas RE1, GE1, and BE1 are maintained as it is and only the first optical member 161 is shifted, the first emission areas RE1, GE1, and BE1 may be disposed to be relatively biased to the top of the first optical member 161. In the similar way, when the second emission areas RE2, GE2, and BE2 are maintained as it is and only the second optical member 162 is shifted, in the plan view, the second emission areas RE2, GE2, and BE2 may be disposed to be relatively biased to the top of the second optical member 162. Therefore, on the cross-section, a center of the first optical member 161 may not match the center of the first emission area RE1, GE1, BE1. Further, a center of the second optical member 162 may not match a center of the second emission area RE2, GE2, BE2.

In the upper area AA2_u of the second active area AA2, all the shifted distances of the center of the first optical member 161 from the centers of the first emission areas RE1, GE1, and BE1 may be the same. Further, in the upper area AA2_u of the second active area AA2, all the shifted distances of the center of the second optical member 162 from the centers of the second emission areas RE2, GE2, and BE2 may be the same.

Further, in the upper area AA2_u of the second active area AA2, the first optical member 161 and the second optical member 162 may be shifted by the same distance. Specifically, all the shifted distances of the center of the first optical member 161 from the centers of the first emission areas RE1, GE1, and BE1 and the shifted distances of the center of the second optical member 162 from the centers of the second emission areas RE2, GE2, and BE2 may be the same. Therefore, in the upper area AA2_u of the second active area AA2, the first optical member 161 and the second optical member 162 may be shifted by the same direction regardless of the position.

When the first optical member 161 and the second optical member 162 are shifted to one side, at least one end of the first optical member 161 and the second optical member 162 may not cover one end of the barrier layer 195 on the cross-section, depending on a shifted amount. For example, referring to FIG. 9, at least some end of the first optical member 161 and the second optical member 162, that is, a left end, may be spaced apart from the barrier layer 195. Therefore, at least some end of the first optical member 161 and the second optical member 162 may be disposed on the second interlayer insulating film 117. However, this is just an example according to a shifted amount of the first optical member 161 and the second optical member 162 so that even though the first optical member 161 and the second optical member 162 are shifted, the end may still be located on the plurality of barrier layers 195. In the upper area AA2_u of the second active area AA2, the first optical member 161 and the second optical member 162 may cover the first emission areas RE1, GE1, and BE1 and the second emission areas RE2, GE2, and BE2, respectively. For example, a maximum width of the first optical member 161 may be larger than the maximum width of the first emission areas RE1, GE1, and BE1. Further, a maximum width of the second optical member 162 may be larger than the maximum width of the second emission areas RE2, GE2, and BE2. Therefore, even though the first optical member 161 and the second optical member 162 are shifted, the first optical member 161 and the second optical member 162 may cover the entire first emission areas RE1, GE1, and BE1 and the entire second emission areas RE2, GE2, and BE2, respectively.

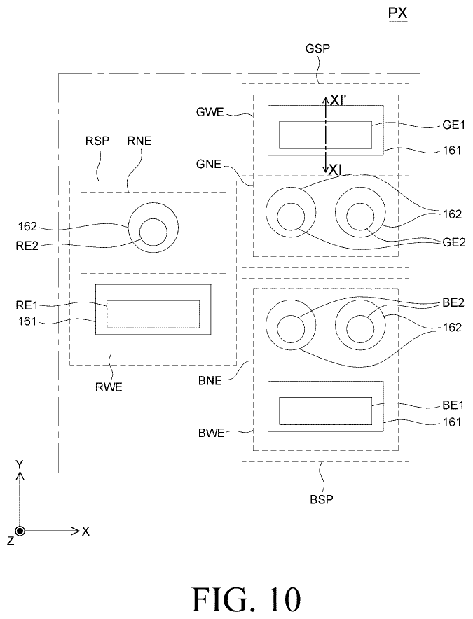

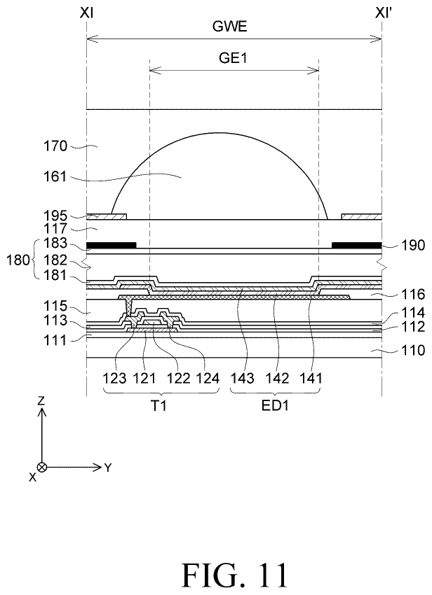

FIG. 10 is an enlarged plan view illustrating placement of an optical member included in a lower area of a second active area of a display device according to an exemplary embodiment of the present disclosure. FIG. 11 is a cross-sectional view taken along the line XI-XI′ of FIG. 10.

Specifically, FIG. 10 is an enlarged plan view of a lower area AA2_d with respect to the panel center line PN_CL in the second active area AA2 of the display device 100 according to the exemplary embodiment of the present disclosure. Further, FIG. 11 is a cross-sectional view illustrating a cross-section with respect to a short side of the first optical member 161 disposed in the lower area AA2_d of the second active area AA2.

All configurations of the lower area AA2_d of the second active area AA2 of FIGS. 10 and 11 are the same as the upper area AA2_u of FIGS. 8 and 9 except a sifting direction of the first optical member 161 and the second optical member 162, so that a redundant description will be omitted.

Referring to FIGS. 10 and 11 together, in the lower area AA2_d of the second active area AA2, the first optical member 161 may be shifted from the center of the first emission area RE1, GE1, BE1 to the other side different from the upper area AA2_u. Further, the second optical member 162 may also be shifted from centers of the second emission areas RE2, GE2, and BE2 to the other side different from the upper area AA2_u. Therefore, the first optical member 161 and the second optical member 162 may be shifted in different directions in the upper area AA2_u and the lower area AA2_d of the second active area AA2. For example, in the upper area AA2_u and the lower area AA2_d of the second active area AA2, the first optical member 161 may be shifted in opposite directions. Further, in the upper area AA2_u and the lower area AA2_d of the second active area AA2, the second optical member 162 may be shifted in opposite directions. Specifically, when the first optical member 161 and the second optical member 162 are shifted downwardly in the upper area AA2_u of the second active area AA2, the first optical member 161 and the second optical member 162 may be shifted upwardly in the lower area AA2_d.

Referring to FIG. 10, in the lower area AA2_d of the second active area AA2, the first optical member 161 and the second optical member 162 may be shifted to the same direction. For example, in the lower area AA2_d of the second active area AA2, a direction in which the first optical member 161 is shifted from the centers of the first emission areas RE1, GE1, and BE1 and a direction in which the second optical member 162 is shifted from the centers of the second emission areas RE2, GE2, and BE2 may be the same. That is, both the first optical member 161 and the second optical member 162 disposed in the lower area AA2_d of the second active area AA2 may be shifted to the same direction regardless of the positions.

For example, in the lower area AA2_d of the second active area AA2, the first optical member 161 may be shifted upwardly from the center of the first emission areas RE1, GE1, and BE1. In this case, the second optical member 162 located in the lower area AA2_d of the second active area AA2 may also be shifted toward the upper direction of the display panel PN. Therefore, both the first optical member 161 and the second optical member 162 disposed in the lower area AA2_d of the second active area AA2 may be shifted toward the upper direction of the display panel PN.

As described above, when the first emission areas RE1, GE1, and BE1 are maintained as it is and only the first optical member 161 is shifted, the first emission areas RE1, GE1, and BE1 may be disposed to be relatively biased to the bottom of the first optical member 161. In the similar way, when the second emission areas RE2, GE2, and BE2 are maintained as it is and only the second optical member 162 is shifted, on the plane, the second emission areas RE2, GE2, and BE2 may be disposed to be relatively biased to the bottom of the second optical member 162. Therefore, on the cross-section, a center of the first optical member 161 may not match centers of the first emission areas RE1, GE1, and BE1. Further, a center of the second optical member 162 may not match centers of the second emission areas RE2, GE2, and BE2.

In the lower area AA2_d of the second active area AA2, all the shifted distances of the center of the first optical member 161 from the centers of the first emission areas RE1, GE1, and BE1 may be the same. Further, in the lower area AA2_d of the second active area AA2, all the shifted distances of the center of the second optical member 162 from the centers of the second emission areas RE2, GE2, and BE2 may be the same.

Further, in the lower area AA2_d of the second active area AA2, the first optical member 161 and the second optical member 162 may be shifted by the same distance. Specifically, all the shifted distances of the center of the first optical member 161 from the centers of the first emission areas RE1, GE1, and BE1 and the shifted distances of the center of the second optical member 162 from the centers of the second emission areas RE2, GE2, and BE2 may be the same. Therefore, in the lower area AA2_d of the second active area AA2, the first optical member 161 and the second optical member 162 may be shifted by the same direction regardless of the position.

Referring to FIG. 11, when the first optical member 161 and the second optical member 162 are shifted to one side, at least one end, that is, a right end of the first optical member 161 and the second optical member 162 may not cover one end of the barrier layer 195 on the cross-section, depending on a shifted amount. For example, right ends of the first optical member 161 and the second optical member 162 may be spaced apart from the barrier layer 195. Therefore, at least some end of the first optical member 161 and the second optical member 162 may be disposed on the second interlayer insulating film 117. However, this is just an example according to a shifted amount of the first optical member 161 and the second optical member 162 so that even though the first optical member 161 and the second optical member 162 are shifted, the end may still be located on the plurality of barrier layers 195. In the lower area AA2_d of the second active area AA2, the first optical member 161 and the second optical member 162 may cover the first emission areas RE1, GE1, and BE1 and the second emission areas RE2, GE2, and BE2, respectively. For example, a maximum width of the first optical member 161 may be larger than the maximum width of the first emission areas RE1, GE1, and BE1. Further, a maximum width of the second optical member 162 may be larger than the maximum width of the second emission areas RE2, GE2, and BE2. Therefore, even though the first optical member 161 and the second optical member 162 are shifted, the first optical member 161 and the second optical member 162 may cover the entire first emission areas RE1, GE1, and BE1 and the entire second emission areas RE2, GE2, and BE2, respectively.

In the meantime, the characteristic of the light emitting diode may be rapidly deteriorated if it is exposed to moisture or oxygen, depending on a constituent material of an emission layer. Therefore, in order to suppress permeation of moisture or oxygen into the light emitting diode from the outside, an encapsulation member may be disposed on the light emitting diode. At this time, the encapsulation member may be formed of a plurality of layers formed of different materials. At this time, at least one of the plurality of encapsulation members may be formed of an organic material. Unlike the inorganic material, the organic material has a flowing nature, so that when at least one encapsulation member includes an organic material, the encapsulation member formed of an organic material may flow toward the outer periphery of the display panel to be inclined. At least one encapsulation member which is formed of the organic material is inclined on the outer periphery of the display panel so that configurations disposed on the encapsulation member may also be inclined together.

As described above, the outer peripheral area on which the encapsulation member is inclined may extend not only to the non-active area, but also to a partial area of the active area. However, when the encapsulation member is inclined in a partial area of the active area, a height of an uppermost end of an optical lens disposed on the encapsulation member may also be lowered. For example, the encapsulation member flows toward the substrate as it goes toward the outer periphery of the active area so that a height of an uppermost end of the optical lens disposed on the encapsulation member may also be decreased toward the outer periphery of the active area.

As described above, the height of the highest end of the optical member is lowered as it goes toward the outer periphery of the active area so that a cut-off angle may be increased. As described above, when the cut-off angle is increased, in the corresponding area, there may be a problem in that the image is not properly recognized, but is brightly recognized. In order to suppress this problem, the non-active area which encloses the active area may be expanded to be larger. However, if the non-active area is expanded, there may be a problem in that a bezel area in which the image is not visible is unnecessarily increased.

Therefore, in the display device 100 according to the exemplary embodiment of the present disclosure, in the second active area AA2 which is an outer peripheral area of the active area AA, the first optical member 161 and the second optical member 162 are shifted to one side. As described above, in the second active area AA2 in which the cut-off angle may be increased, the first optical member 161 and the second optical member 162 are shifted to suppress the increase of the cut-off angle.

That is, the first optical member 161 and the second optical member 162 are shifted to maintain the cut-off angle of the second active area AA2 which is an edge area to be equal to the first active area AA1 which is a center area. Therefore, the difference in the luminance of the first active area AA1 and the second active area AA2 may be reduced.

Therefore, the entire luminance of the first active area AA1 and the second active area AA2 may be uniformly maintained. Therefore, the phenomenon that the image is not properly recognized, but is brightly recognized in the second active area AA2 may be improved. Therefore, a high quality image with a uniform luminance may be implemented in the entire active area AA.

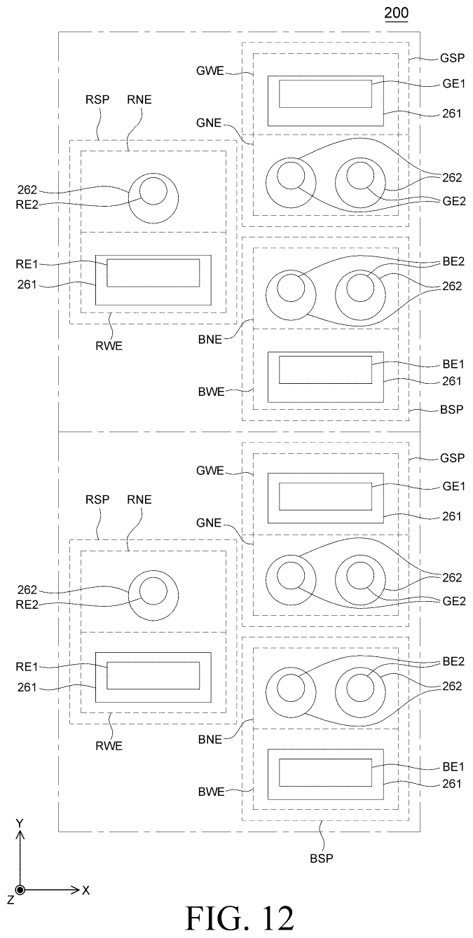

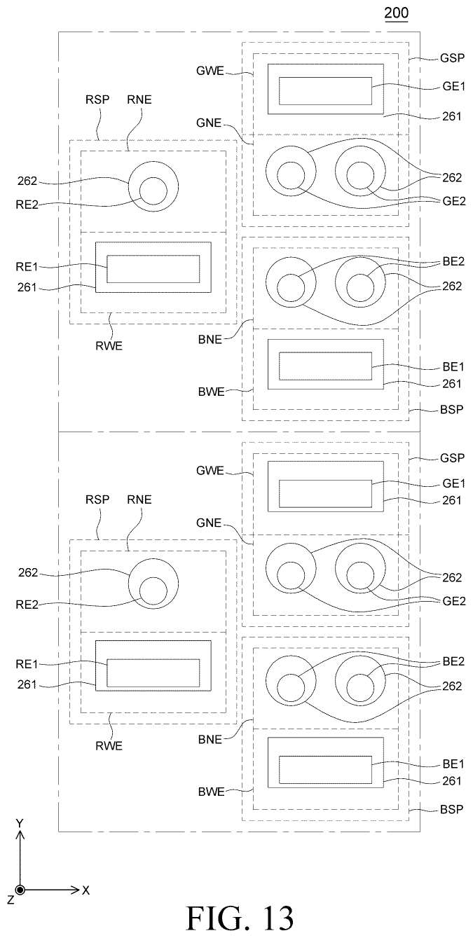

FIG. 12 is an enlarged plan view illustrating placement of an optical member included in an upper area of a second active area of a display device according to another exemplary embodiment of the present disclosure. FIG. 13 is an enlarged plan view illustrating placement of an optical member included in a lower area of a second active area of a display device according to another exemplary embodiment of the present disclosure.

Specifically, FIG. 12 is an enlarged plan view of an upper area AA2_u with respect to a panel center line PN_CL in a second active area AA2 of a display device 200. FIG. 13 is an enlarged plan view of a lower area AA2_d with respect to a panel center line PN_CL in a second active area AA2 of a display device 200. The only difference between a display device 200 of FIGS. 12 and 13 and the display device 100 of FIGS. 1 to 11 is a shifted amount of a first optical member 261 and a second optical member 262, but the other configurations are substantially the same, so that a redundant description will be omitted.

Referring to FIGS. 12 and 13, in the upper area AA2_u of the second active area AA2, both the first optical member 261 and the second optical member 262 may be shifted to the same direction. Specifically, in the upper area AA2_u of the second active area AA2, both the first optical member 261 and the second optical member 262 may be shifted downwardly.

At this time, in the upper area AA2_u of the second active area AA2, all the shifted distances of the first optical member 261 and the second optical member 262 may be different in each pixel PX. For example, all the shifted distances of the first optical member 261 and the second optical member 262 disposed in one pixel PX may be the same. In contrast, shifted distances of the first optical member 261 and the second optical member 262 disposed in pixels PX adjacent to each other in the second direction Y may be different from each other. Specifically, shifted distances of the first optical member 261 and the second optical member 262 disposed in a pixel PX which is located relatively higher on the plane may be different from shifted distances of the first optical member 261 and the second optical member 262 disposed in a pixel PX which is located relatively lower.

Referring to FIG. 12, in the upper area AA2_u of the second active area AA2, the shifted distances of the first optical member 261 and the second optical member 262 may be increased upwardly. Specifically, in the upper area AA2_u of the second active area AA2, the first optical member 261 and the second optical member 262 which are disposed relatively higher may be shifted downwardly more than the first optical member 261 and the second optical member 262 which are disposed relatively lower.

As described above, as the first optical member 261 and the second optical member 262 are shifted downwardly, uppermost ends of the first optical member 261 and the second optical member 262 may be close to uppermost ends of the first emission areas RE1, GE1, and BE1 and the second emission areas RE2, GE2, and BE2 on the plane. For example, a distance from an uppermost end of the first optical member 261 which is disposed relatively higher to an uppermost end of the first emission areas RE1, GE1, and BE1 may be shorter than a distance from an uppermost end of the first optical member 261 which is disposed relatively lower to the uppermost end of the first emission areas RE1, GE1, and BE1. In the similar way, a distance from an uppermost end of the second optical member 262 which is disposed relatively higher to an uppermost end of the second emission areas RE2, GE2, and BE2 may be shorter than a distance from an uppermost end of the second optical member 262 which is disposed relatively lower to the uppermost end of the second emission areas RE2, GE2, and BE2.

In contrast, referring to FIG. 13, for example, in the lower area AA2_d of the second active area AA2, the shifted distances of the first optical member 261 and the second optical member 262 may be increased downwardly. Specifically, in the lower area AA2_d of the second active area AA2, the first optical member 261 and the second optical member 262 which are disposed relatively lower may be shifted upwardly more than the first optical member 261 and the second optical member 262 which are disposed relatively higher.

As described above, as the first optical member 261 and the second optical member 262 are shifted upwardly, lowermost ends of the first optical member 261 and the second optical member 262 may be close to lowermost ends of the first emission areas RE1, GE1, and BE1 and the second emission areas RE2, GE2, and BE2 on the plane. For example, a distance from a lowermost end of the first optical member 261 which is disposed relatively lower to a lowermost end of the first emission areas RE1, GE1, and BE1 may be shorter than a distance from an lowermost end of the first optical member 261 which is disposed relatively higher to the lowermost end of the first emission areas RE1, GE1, and BE1. In the similar way, a distance from the lowermost end of the second optical member 262 which is disposed relatively lower to the lowermost end of the second emission areas RE2, GE2, and BE2 may be shorter than a distance from the lowermost end of the second optical member 262 which is disposed relatively higher to the lowermost end of the second emission areas RE2, GE2, and BE2.

In the meantime, also in the second active area AA2 of the active area AA, the more adjacent to the outer periphery, that is, the non-active area NA, the more severe the inclination of the encapsulation member 180. As described above, the more severe the inclination of the encapsulation member 180, the larger the cut-off angle. Therefore, in the display device 200 according to another exemplary embodiment of the present disclosure, the shifted distances of the first optical member 261 and the second optical member 262 may be increased upwardly in the upper area AA2_u of the second active area AA2, and increased downwardly in the lower area AA2_d. By doing this, the severity of the cut-off angle increased toward the outer periphery in the second active area AA2 may be suppressed.

As described above, the shifted distances of the first optical area 261 and the second optical area 262 in the second active area AA2 are set to be different so that the luminance difference which may be generated in the second active area AA2 may be reduced. Therefore, the luminance difference between the first active area AA1 and the second active area AA2 may also be reduced.

Therefore, the entire luminance of the first active area AA1 and the second active area AA2 may be more uniformly maintained. Accordingly, the phenomenon that the image is not properly recognized, but is brightly recognized in the second active area AA2 may be more improved. Therefore, a high quality image with a more uniform luminance may be implemented in the entire active area AA.

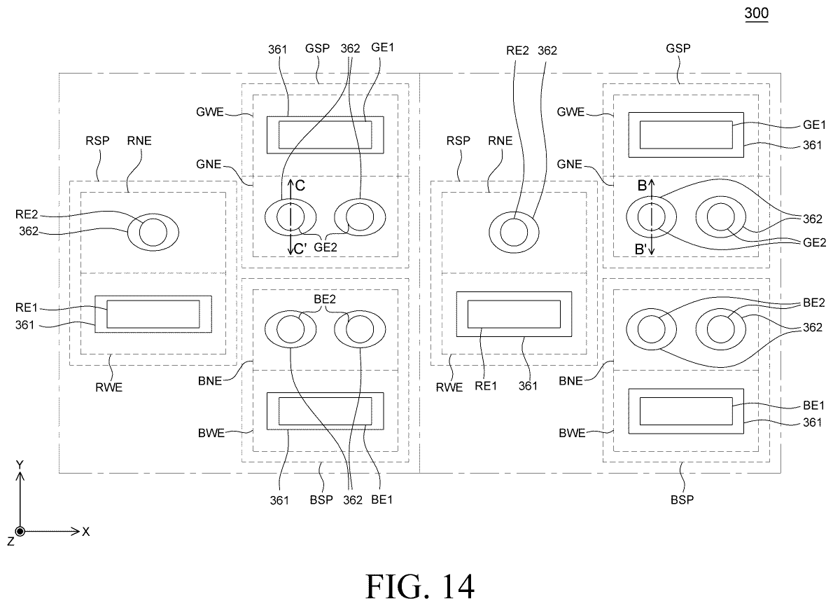

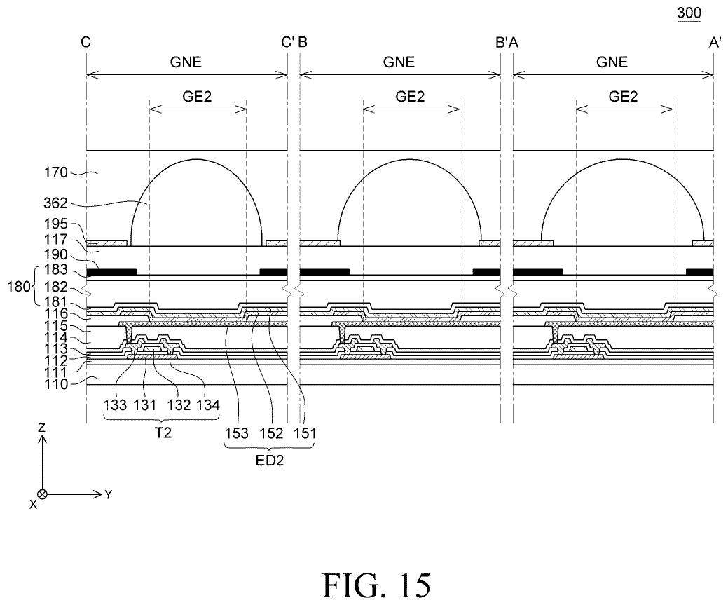

FIG. 14 is an enlarged plan view illustrating placement of an optical member included in a left area of a second active area of a display device according to another exemplary embodiment of the present disclosure. FIG. 15 is a cross-sectional view illustrating an example taken along lines A-A′ of FIG. 5, B-B′ and C-C′ of FIG. 14.

Specifically, FIG. 14 is an enlarged plan view of a second active area AA2 of a display device 300. FIG. 15 illustrates a cross-sectional view taken along the line A-A′ which is a cross-sectional shape of a short side direction of a second optical member 162 disposed in a first active area AA1 of a display device 300. Further, FIG. 15 illustrates a cross-sectional view taken along lines B-B′ and C-C′ which are cross-sectional shapes in a short side direction of a second optical member 362 disposed in a second active area AA2.

The only difference between a display device 300 of FIGS. 14 and 15 and the display device 100 of FIGS. 1 to 11 is a first optical member 361 and a second optical member 362, but the other configurations are substantially the same, so that a redundant description will be omitted.

Referring to FIG. 14, in the second active area AA2, a vertical width of the first optical member 361 and the second optical member 362 may be smaller than a vertical width of the first optical member 161 and the second optical member 162 disposed in the first active area AA1. Specifically, even though it is not illustrated in the drawing, in the first active area AA1, the first optical member 161 and the second optical member 162 may have a uniform size. For example, in the first active area AA1, all the first optical members 161 may have the same size on the plane. Further, in the first active area AA1, all the second optical members 162 may have the same size on the plane.

In contrast, in the second active area AA2, a vertical width of the first optical member 361 and the second optical member 362 on the plane may be smaller than those of the first optical member 161 and the second optical member 162 of the first active area AA1.

Specifically, in the second active area AA2, a width in a vertical direction, that is, a short-side direction of the first optical member 361 may be smaller than that of the first optical member 161 of the first active area AA1. Likewise, the second optical member 362 in the second active area AA2 may have a vertical width smaller than that of the second optical member 162 of the first active area AA1. Therefore, on the plane, the second optical member 362 of the second active area AA2 may have a width in a vertical direction, that is, a second direction Y, smaller than a width in a horizontal direction, that is, a first direction X.

Even though it is not illustrated in the drawing, in the second active area AA2, the first optical member 361 and the second optical member 362 may have a uniform size on the plane. For example, in the second active area AA2, all the first optical members 361 may have the same size on the plane. Further, in the second active area AA2, all the second optical members 362 may have the same size on the plane.

Further, when it is described with reference to FIG. 14, the first optical member 361 and the second optical member 362 which are disposed in one pixel PX in the second active area AA2 may have a uniform size on the plane. For example, all the first optical members 361 disposed in one pixel PX of the second active area AA2 may have a uniform size on the plane. Further, all the second optical members 362 disposed in one pixel PX of the second active area AA2 may have a uniform size on the plane.

In the second active area AA2, the closer to the outer periphery (corresponding to a left side in FIG. 14), the smaller the vertical width of the first optical member 361 and the second optical member 362. FIG. 14 is an enlarged plan view of a second active area AA2 disposed at the left side of the display panel PN, in the second active area AA2. Therefore, in FIG. 14, the outer peripheral direction may refer to a left side. Referring to this, in the second active area AA2, the closer to the outer peripheral direction, that is, to the left side, the smaller the vertical width of the first optical member 361 and the second optical member 362. Specifically, a vertical width of the first optical member 361 and the second optical member 362 disposed in one pixel PX which is located more outside may be smaller than a vertical width of the first optical member 361 and the second optical member 362 disposed in the other pixel PX adjacent thereto at the right side.

In the meantime, even though it is not illustrated in the drawing, in a second active area AA2 located at the right side of the display panel PN, a vertical width of the first optical member 361 and the second optical member 362 disposed in one pixel PX located at the right side, which is more outside may be smaller than a vertical width of the first optical member 361 and the second optical member 362 disposed in the other pixel PX located to the left side more.

In a second active area AA2 located above the display panel PN, a vertical width of the first optical member 361 and the second optical member 362 disposed in one pixel PX located at the upper portion, which is more outside, may be smaller than a vertical width of the first optical member 361 and the second optical member 362 disposed in the other pixel PX which is located lower.

Further, in a second active area AA2 located below the display panel PN, a vertical width of the first optical member 361 and the second optical member 362 disposed in one pixel PX located at the lower portion, which is more outside, may be smaller than a vertical width of the first optical member 361 and the second optical member 362 disposed in the other pixel PX which is located higher.

FIG. 15 illustrates a first active area AA1 and a second active area AA2 located at the left side of the display panel PN, in which when it goes to the left side, it means an outer periphery of the display panel PN. Referring to FIG. 15, on the cross-section, the closer to the outer periphery, that is, the left side of the second active area AA2 from the first active area AA1, the smaller the width in the second direction Y. In contrast, in the entire first active area AA1 and second active area AA2, thicknesses of the first optical members 161 and 361 and the second optical members 162 and 362 in the third direction Z may be the same. As another example, in the entire first active area AA1 and second active area AA2, the first optical members 161 and 361 and the second optical members 162 and 362 may have the same maximum thicknesses. Therefore, the closer to the outer periphery of the display panel PN, the larger the ratio of the width in the second direction Y and a width in the third direction Z in the second active area AA2.

Further, in at least a partial area of the second active area AA2, both ends of the second optical member 362 may not be disposed on the barrier layer 195. For example, the width in the second direction Y is reduced toward the outer periphery in the second active area AA2 so that in at least a part of the outer peripheral area, both ends of the second optical member 362 may be spaced apart from the barrier layer 195.

In the meantime, even though in FIGS. 14 and 15, it is illustrated that the first optical member 361 and the second optical member 362 are not shifted, the present disclosure is not limited thereto. For example, the first optical member 361 and the second optical member 362 disposed in the second active area AA2 of another display device 300 of the present disclosure may be shifted in the same way as the first optical members 161 and 261 and the second optical members 162 and 262 of the display devices 100 and 200 of FIGS. 1 to 13.

As described above, in the display device 300 according to still another exemplary embodiment of the present disclosure, in the second active area AA2, the closer to the outer periphery of the display panel PN, the smaller the width of the first optical member 361 and the second optical member 362 in the second direction Y. Further, a ratio of the width in the second direction Y and a thickness in the third direction Z of the first optical member 361 and the second optical member 362 may vary. By doing this, the severity of the cut-off angle increased in the second active area AA2 may be suppressed.

Further, a ratio of a width in the second direction Y and a thickness in the third direction Z of the first optical member 361 and the second optical member 362 in the second active area AA2 is set to be different so that the luminance difference which may be generated in the second active area AA2 may be reduced. Therefore, the luminance difference between the first active area AA1 and the second active area AA2 may be more reduced.

Therefore, the entire luminance of the first active area AA1 and the second active area AA2 may be more uniformly maintained. Accordingly, the phenomenon that the image is not properly recognized, but is brightly recognized in the second active area AA2 may be more improved. Therefore, a high quality image with a more uniform luminance may be implemented in the entire active area AA.

The exemplary embodiments of the present disclosure can also be described as follows:

A display device according to an aspect of the present disclosure comprises a substrate including an active area which includes a first active area and a second active area which encloses the first active area and includes an upper area and a lower area, a first light emitting diode which is disposed in the active area and includes a first emission area, a first optical member disposed on the first light emitting diode, a second light emitting diode which is disposed in the active area, emits the same color light as the first light emitting diode, and includes a second emission area; and a second optical member which is disposed on the second light emitting diode and has a shape different from that of the first optical member, wherein in the second active area, the first optical member is shifted from a center of the first emission area to one side and the second optical member is shifted from a center of the second emission area to one side.

In an upper area of the second active area, the first optical member and the second optical member may be shifted to the same direction and in a lower area of the second active area, the first optical member and the second optical member may be shifted to the same direction.

The first optical member and the second optical member may be shifted in different directions in the upper area and the lower area of the second active area.

In the upper area, the first optical member and the second optical member may be shifted toward the lower area, and in the lower area, the first optical member and the second optical member may be shifted toward the upper area.

All shifted distances of a center of the first optical member from the center of the first emission area may be the same and all shifted distances of a center of the second optical member from the center of the second emission area may be the same.

The shifted distance of the center of the first optical member from the center of the first emission area and the shifted distance of the center of the second optical member from the center of the second emission area may be the same.

In the upper area of the second active area, the closer to top, it may be the larger the shifted distances of the first optical member and the second optical member and in a lower area of the second active area, the closer to bottom, it may be the larger the shifted distances of the first optical member and the second optical member.

The display device may further comprise a barrier layer disposed on the first light emitting diode and the second light emitting diode, wherein in the first active area, ends of the first optical member and the second optical member may be disposed on the barrier layer and in the second active area, at least one end of the first optical member and the second optical member may be spaced apart from the barrier layer.

In the second active area, the closer to outer periphery, it may be the smaller heights of uppermost ends of the first optical member and the second optical member.

A display device according to another aspect of the present disclosure comprises a substrate including an active area which includes a first active area and a second active area which encloses the first active area, a first light emitting diode and a second light emitting diode which are disposed in the active area, a first optical member disposed on the first light emitting diode; and a second optical member which is disposed on the second light emitting diode and has a planar shape different from that of the first optical member, wherein in the second active area, the closer to outer periphery, the smaller widths of the first optical member and the second optical member.

The first optical member and the second optical member may have the same largest thickness.

The planar shape of the first optical member may be a bar shape having a long side and a short side perpendicular to the long side and the first optical member may have the width in a short side direction which may be reduced toward the outer periphery in the second active area.

In the second active area, the width of the second optical member may be reduced toward the outer periphery in the same direction as the short side direction of the first optical member.

In the first active area, each of the first optical member and the second optical member may have the same width in the short side direction of the first optical member.

In the second active area, it may be the closer to the outer periphery, the smaller heights of uppermost ends of the first optical member and the second optical member.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate having an active area including:
a first active area; and
a second active area which encloses the first active area, the second active area including an upper area and a lower area;
a light emitting diode which is disposed in the active area and includes an emission area; and
an optical member on the light emitting diode,
wherein in the upper area or the lower area of the second active area, a center of the optical member is shifted from a center of the emission area.

2. The display device according to claim 1, wherein the light emitting diode includes a first light emitting diode which has a first emission area and a second light emitting diode which emits a same color light as the first light emitting diode and has a second emission area,
wherein the optical member includes a first optical member on the first light emitting diode and a second optical member on the second light emitting diode and has a shape different from that of the first optical member,
wherein in the upper area or the lower area of the second active area, a center of the first optical member is shifted from a center of the first emission area, and a center of the second optical member is shifted from a center of the second emission area.

3. The display device according to claim 2, wherein in the upper area of the second active area, the first optical member and the second optical member are shifted to a same direction, and in the lower area of the second active area, the first optical member and the second optical member are shifted to a same direction.

4. The display device according to claim 1, wherein the optical member is shifted in the upper area and the lower area of the second active area in different directions.

5. The display device according to claim 4, wherein in the upper area of the second active area, the optical member is shifted toward the lower area, and in the lower area of the second active area, the optical member is shifted toward the upper area.

6. The display device according to claim 1, wherein in the upper area of the second active area, all shifted distances of the center of the optical member from the center of the emission area are the same, or
wherein in the lower area of the second active area, all shifted distances of the center of the optical member from the center of the emission area are the same.

7. The display device according to claim 1, wherein in the upper area of the second active area, a shifted distance of the center of the first optical member from the center of the first emission area and a shifted distance of the center of the second optical member from the center of the second emission area are the same, or
wherein in the lower area of the second active area, a shifted distance of the center of the first optical member from the center of the first emission area and a shifted distance of the center of the second optical member from the center of the second emission area are the same.

8. The display device according to claim 1, wherein in the upper area or the lower area of the second active area, the closer to outer periphery of the substrate, the larger the shifted distance of the optical member.

9. The display device according to claim 1, further comprising:
a barrier layer on the light emitting diode,
wherein in the first active area, ends of the optical member are on the barrier layer, and in the upper area or the lower area of the second active area, at least one end of the optical member is spaced apart from the barrier layer.

10. The display device according to claim 1, wherein in the second active area, the closer to outer periphery of the substrate, the smaller heights of uppermost ends of the optical member.

11. The display device according to claim 1, wherein a width of the optical member disposed in a left area or a right area of the second active area is smaller than a width of the optical member disposed in the first active area.

12. The display device according to claim 11, wherein the width of the optical member disposed in the left area or the right area of the second active area in a direction from the upper area to the lower area is smaller than the width of the optical member disposed in the first active area in the direction from the upper area to the lower area.

13. The display device according to claim 11, wherein in the left area or the right area of the second active area, the closer to outer periphery of the substrate, the smaller width of the width of the optical member.

14. A display device, comprising:
a substrate having an active area including:
a first active area; and
a second active area which encloses the first active area;
a light emitting diode disposed in the active area; and
a optical member on the light emitting diode,
wherein in the second active area, the closer to outer periphery of the substrate, the smaller width of the optical member.

15. The display device according to claim 14, wherein in the second active area, the closer to the outer periphery of the substrate in a first direction, the smaller width of the optical member in a second direction perpendicular to the first direction.

16. The display device according to claim 14, wherein the light emitting diode includes a first light emitting diode and a second light emitting diode which emit the same color,
wherein the optical member includes a first optical member on the first light emitting diode and a second optical member on the second light emitting diode and has a planar shape different from that of the first optical member.

17. The display device according to claim 16, wherein in the second active area, the first optical member and the second optical member have the same largest thickness.

18. The display device according to claim 16, wherein the planar shape of the first optical member is a bar shape having a long side and a short side perpendicular to the long side, and in the second active area, the width of the short side of the first optical member is reduced toward the outer periphery of the substrate.

19. The display device according to claim 18, wherein in the second active area, the width of the second optical member in a direction of the short side of the first optical member is reduced toward the outer periphery of the substrate.

20. The display device according to claim 15, wherein in the first active area, the optical member has the same width in the second direction.

21. The display device according to claim 14, wherein in the second active area, the closer to the outer periphery of the substrate, the smaller height of uppermost end of the optical member.

22. The display device according to claim 2, further comprising a barrier layer disposed to overlap a region between a first optical member and a second optical member included in a same pixel,
wherein the barrier layer, in operation, is configured to suppress lateral light leakage between the first and second optical members.
